(19) United States
(12) Patent Application Publication
(10) Pub. No.: US 2022/0148899 A1
(43) Pub. Date: May 12, 2022

(54) WAFER BOAT STRUCTURE, AS WELL AS WAFER BOAT ASSEMBLY AND DIFFUSION FURNACE WITH SAME

(71) Applicant: CHANGXIN MEMORY TECHNOLOGIES, INC., Hefei City (CN)

(72) Inventor: Pengfei GAO, Hefei (CN)

(21) Appl. No.: 17/487,685

(22) Filed: Sep. 28, 2021

Related U.S. Application Data
(63) Continuation of application No. PCT/CN2021/103828, filed on Jun. 30, 2021.

(30) Foreign Application Priority Data
Nov. 6, 2020 (CN) 202011228207.6

(51) Int. Cl. H01L 21/673; H01L 21/687; C30B 31/10

(52) U.S. Cl. CPC H01L 21/67309; C30B 31/103; H01L 21/68771

(57) ABSTRACT

A wafer boat structure as well as a wafer boat assembly and a diffusion furnace with the wafer boat structure are provided. The wafer boat structure includes a supporting frame and a wafer supporting part. The supporting frame includes an upper supporting member and a lower supporting member. A plurality of supporting rods are arranged between the upper supporting member and the lower supporting member. An opening for access of wafers is formed between each two adjacent supporting rods. The wafer supporting part is arranged on the supporting rods for supporting the wafer. The wafer supporting part comprises a supporting plate and at least one wafer board. The wafer board is arranged on the inner side of the supporting rod so as to support the edge of the wafer.

### CROSS-REFERENCE TO RELATED APPLICATION

This is a continuation application of International Patent Application No. PCT/CN2021/103828, filed on Jun. 30, 2021, which claims priority to Chinese patent application No. 202011228207.6, filed on Nov. 6, 2020, and entitled “WAFER BOAT STRUCTURE, AS WELL AS WAFER BOAT ASSEMBLY AND DIFFUSION FURNACE WITH SAME”. The disclosures of International Patent Application No. PCT/CN2021/103828 and Chinese patent application No. 202011228207.6 are incorporated by reference herein in their entireties.

### TECHNICAL FIELD

The disclosure relates to the technical field of semiconductors, in particular to a wafer boat structure, as well as a wafer boat assembly and a diffusion furnace.

### BACKGROUND

In the relevant art, storage of wafers is particularly important in the preparation or transportation process of the wafers. In the manufacturing process of the wafers, and particularly in the manufacturing process of the wafers of 12 inch or below, a wafer boat structure is configured to store the wafers in a diffusion furnace device for example. A three-point design is generally adopted in a general wafer boat structure, the wafer is easier to be broken under stress due to change in temperature. The wafer boat structure in the relevant art adopts the three-point design, the centers of the wafers may not be born and supported. Then the wafer is easier to deform in a high-temperature environment. Particularly, when the stress increases after a film thickness is accumulated to a certain degree, the probability of breakage of the wafer is greatly increased, and meanwhile, the problem of non-uniform film formation in the center and at the periphery of the wafer may also occur due to wafer deformation.

### SUMMARY

According to first aspect of the present disclosure, a wafer boat structure includes a supporting frame and at least one wafer supporting part. The supporting frame includes an upper supporting member and a lower supporting member. A plurality of supporting rods are arranged between the upper supporting member and the lower supporting member. One end of each of the supporting rods is connected with the upper supporting member and the other end is connected with the lower supporting member. The plurality of supporting rods are spaced apart from each other in the circumferential direction of the upper supporting member. An opening for access of wafers is formed between each two adjacent supporting rods. The wafer supporting part is arranged on the supporting rods for supporting the wafers. The wafer supporting part includes a supporting plate and at least one wafer board. The supporting plate and the at least one wafer board support the same wafer. The supporting plate is connected with the supporting rod and the position of the supporting plate corresponds to the central positions of the upper supporting member and the lower supporting member. The wafer board is arranged on the inner side of the supporting rod to support the edge of the wafer.

According to second aspect of the present disclosure, a wafer boat assembly is provided. The wafer boat assembly includes the wafer boat structure according to the abovementioned embodiment of the disclosure, and a wafer conveying device. The wafer conveying device includes a wafer conveying arm in the form of a U-shaped structure. An opening of the U-shaped structure faces towards the wafer boat structure. A width of the opening of the U-shaped structure being larger than a maximum width of the supporting plate, for passage of the wafers through the supporting plate.

According to third aspect of the present disclosure, a diffusion furnace is provided. The diffusion furnace includes the wafer boat structure according to the abovementioned embodiment of the disclosure.

### BRIEF DESCRIPTION OF THE DRAWINGS

FIG. 1 is a schematic view of a wafer boat structure and a wafer according to an embodiment of the disclosure.

FIG. 2 is a schematic view of a wafer and a wafer supporting part according to an embodiment of the disclosure.

FIG. 3 is another schematic view of a wafer and a wafer supporting part according to an embodiment of the disclosure, seen from another angle.

FIG. 4 is another schematic view of a wafer and a wafer supporting part according to another embodiment of the disclosure, seen from another angle.

FIG. 5 is another schematic view of a wafer and a wafer supporting part according to another embodiment of the disclosure, seen from another angle.

### DETAILED DESCRIPTION

A wafer boat structure, a wafer boat assembly and a diffusion furnace will be described in further detail below with reference to the accompanying drawings and the following embodiments.

The wafer boat structure 100 according to an embodiment of the disclosure will be described below with reference to the accompanying drawings.

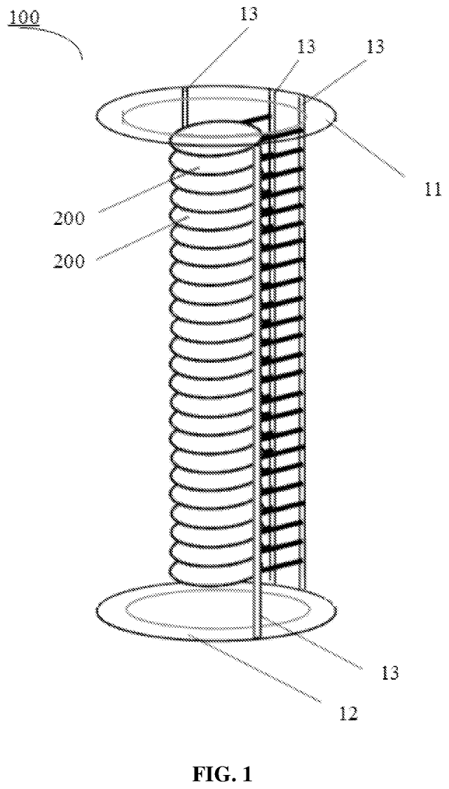

As shown in FIG. 1, the wafer boat structure 100 according to the embodiment of the disclosure includes a supporting frame and wafer supporting parts, the supporting frame includes an upper supporting member 11, a lower supporting member 12 and a plurality of supporting rods 13. The plurality of supporting rods 13 are arranged between the upper supporting member 11 and the lower supporting member 12. One end of each supporting rod 13 is connected with the upper supporting member 11 and another end is connected with the lower supporting member 12. The plurality of supporting rods 13 are spaced apart from one another in the circumferential direction of the upper supporting member 11, and an opening for access of the wafers is formed between each two adjacent supporting rods 13.

In some embodiments, the upper supporting member 11 and the lower supporting member 12 are spaced apart from one another in a vertical direction. The upper supporting member 11 and the lower supporting member 12 may be in the form of a closed ring-shaped structure for improving the stability of the upper supporting member 11 and the lower supporting member 12. In some embodiments, the lower supporting member 12 and the upper supporting member 11 may be in the shape of a circular ring. The supporting rods 13 are arranged between the upper supporting member 11 and the lower supporting member 12. Two ends of each supporting rod 13 are connected with the upper supporting member 11 and the lower supporting member 12 respectively and are parallel to each other. The positions of the supporting rods 13 may be fixed through the upper supporting member 11 and the lower supporting member 12. The number of the supporting rods 13 may be determined according to actual needs. In some embodiments, the number of the supporting rods 13 may be three or more for improving the stability of the supporting frame structure, and as shown in FIG. 1, there may be four supporting rods 13 in this embodiment of the disclosure.

A certain storage space is formed between the plurality of supporting rods 13, the upper supporting member 11 and the lower supporting member 12. Wafers 200 are placed in the storage space, and in order to facilitate placement of the wafers 200, at least two adjacent supporting rods 13 are spaced apart from each other at a certain distance to form an opening for access of the wafers to the storage space.

Each of the wafer supporting parts is arranged on the supporting rods 13 to carry the wafers, each wafer supporting part includes a supporting plate 21 and at least one wafer board 22, the supporting plate 21 and the at least one wafer board 22 support the same wafer. The supporting plate 21 is connected to the supporting rod 13, and the position of the supporting plate 21 corresponds to the central positions of the upper supporting member 11 and the lower supporting member 12. The wafer board 22 is arranged on the inner side of the supporting rod 13 to support the edge of the wafer.

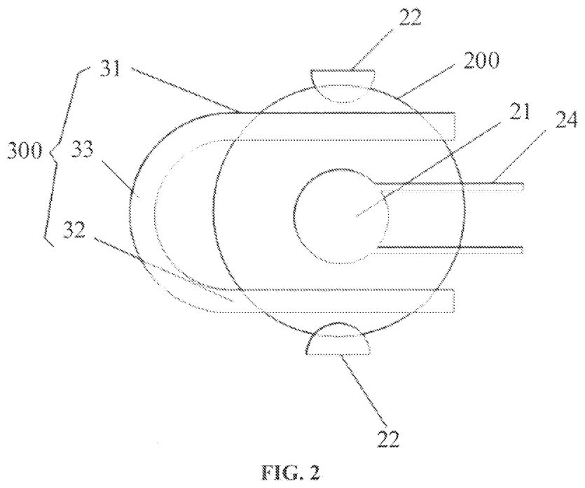

As shown in FIG. 2, in some embodiments, the wafer supporting parts are arranged on the supporting rods 13 and located in the storage space. The wafers 200 are placed on the wafer supporting parts after entering the storage space. There may be a plurality of wafer supporting parts spaced apart from each other in the axial direction of the supporting rods 13. For example, as shown in FIG. 1, the plurality of wafer supporting parts spaced apart from each other in the vertical direction are arranged to support the plurality of wafers 200. Each wafer supporting part includes a supporting plate 21 and at least one wafer board 22. The wafer board 22 and the supporting plate 21 of the same wafer supporting part jointly support the same wafer 200.

The supporting plate 21 and the wafer board 22 are located in the storage space and connected with the supporting rod 13. The supporting plate 21 and the wafer board 22 may be supported and fixed through the supporting rod 13. When viewed from the vertical direction, the position of the supporting plate 21 corresponds to the center positions of the upper supporting member 11 and the lower supporting member 12, so that when the wafer 200 is supported on the wafer supporting part, the supporting plate 21 may support the central portion of the wafer 200. It should be noted that the central portion of the wafer 200 here refers to an area extending outward within a certain range from the center of the wafer 200. The supporting plate 21 substantially corresponds to the central area of the wafer 200, and the supporting plate 21 is capable of supporting a certain area or range of the central area of the wafer 200.

The wafer board 22 is arranged on the inner side of the supporting rod 13 forming the storage space. After the wafer 200 is placed in the storage space, the wafer board 22 may support the edge of the wafer 200. Therefore, by means of the cooperation of the supporting plates 21 and the wafer board 22, the wafer 200 may be supported in such a way that both of the edge and the center of the wafer 200 can be supported. The risk of breakage of the wafer 200 due to the stress in the manufacturing process may be reduced, the product scrappage caused by breakage of wafer 200 may be improved, and the problem that the film forming on the wafer 200 are not uniform at center and edge may also be improved.

In some embodiments of the disclosure, as shown in FIGS. 2 to 5, the wafer supporting part further includes a connecting rod 24 which is connected to the supporting rod 13 and to the supporting plate 21. The position of the supporting plate 21 corresponds to the central area of the wafer. By the connecting rod 24 connected between the supporting plate 21 and the supporting rod 13, the supporting plate 21 may arranged at the position corresponding to the center positions of the upper supporting member 11 and the lower supporting member 12, and the position of the supporting plate 21 may be fixed.

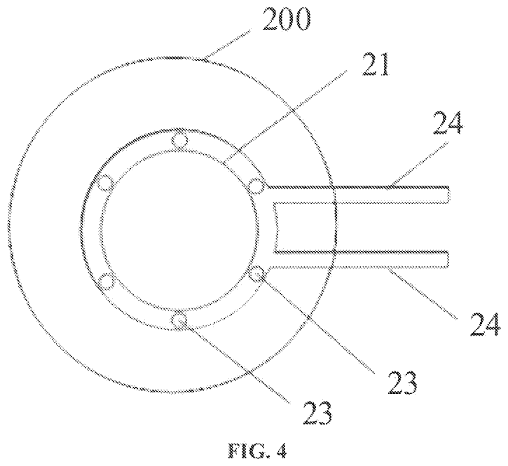

In some embodiments, one end of the connecting rod 24 is connected to the supporting rod 13, the other end of the connecting rod 24 is connected to the supporting plate 21. Each supporting plate 21 may be fixedly supported by one or more connecting rods 24. In some embodiments, each supporting plate 21 may be connected and fixed by at least two connecting rods 24 which may be connected with at least two supporting rods 13 in one-to-one correspondence, so that the stability of the wafer boat structure 100 may be improved. As shown in FIGS. 2 and 4, there may be two connecting rods 24 for each supporting plate, and the two connecting rods 24 are respectively connected with the two supporting rods 13. In some embodiments. The two connecting rods 24 may be connected to two adjacent supporting rods 13, respectively. In some embodiments, the connecting rods 24 may be arranged on the side, away from and opposite to the openings, of the supporting plate, i.e., the connecting rods 24 may be connected to the supporting rods 13 corresponding to the openings, thereby facilitating placement of the wafer 200 on the supporting plate 21 to avoid contact or collision of the wafer 200 with the connecting rods 24.

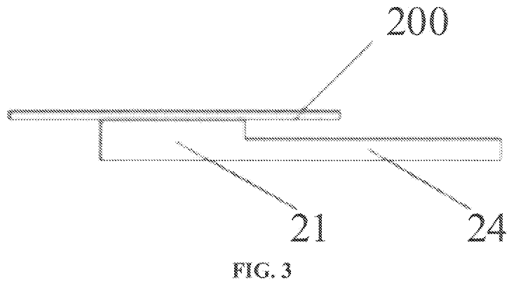

As shown in FIGS. 2 and 3, the upper surface of the supporting plate 21 is flush with the upper surface of the wafer board 22 of the same wafer supporting part and is higher than the upper surface of the connecting rod 24. In this way, the wafer is supported on the wafer supporting part by the upper surface of the supporting plate 21 and the upper surface of the corresponding wafer board 22, and thus the wafer 200 is placed more stably. In addition, the surface of the wafer 200 is separated from the upper surface of the connecting rods 24, so that the contact between the wafer 200 and the connecting rods 24 may be reduced, the contact pollution is reduced, and the problems of collision or abrasion caused by contact are avoided.

In some embodiments, a plurality of wafer boards 22 are provided and the plurality of wafer boards are regularly distributed around the circumference of the supporting plate 21. The plurality of wafer boards 22 in the same plane may support the same wafer 200, and thus the supporting of the wafer 200 is more stable.

As for the shape of the supporting plate 21, the supporting plate 21 may be in a round shape, and in some embodiments, the supporting plate 21 may have a diameter of 90 mm to 110 mm. In another example, the supporting plate 21 may be in a ring shape, for example, the supporting plate 21 may be in a circular ring shape, the inner ring diameter of the supporting plate 21 is 90 mm to 110 mm, and the width of the supporting plate 21 is 6 mm to 10 mm. Therefore, the contact area between the supporting plate 21 and the wafer 200 may be reduced, then the wafer 200 may be conveniently placed, and the manufacturing process operation of a semiconductor device on the wafer 200 may also be avoided. The specific dimensions of the supporting plate 21 may be determined according to actual needs, for example, according to the size of the wafer 200 that needs to be placed. In some embodiments, in case that the diameter of the wafer 200 is 300 mm, the diameter of the supporting plate 21 may be 100 mm when the supporting plate 21 is a circular plate, and the diameter of the inner ring of the supporting plate 21 may be 100 mm when the supporting plate 21 is a circular ring, and the width of the circular ring of the supporting plate 21 may be 8 mm.

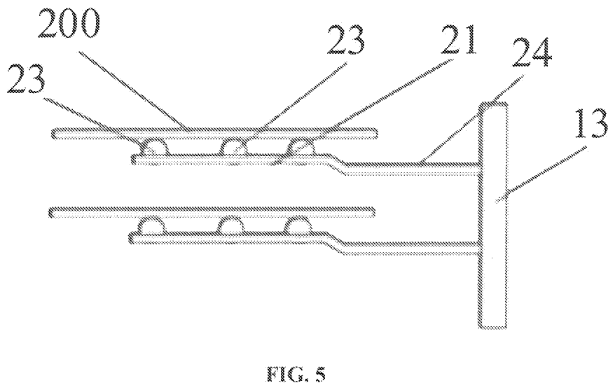

In some embodiments, as shown in FIGS. 4 and 5, a plurality of protrusions 23 may be formed on the supporting plate 21 to support the wafer 200. The plurality of protrusions 23 may allow the wafer 200 and the surface of the supporting plate 21 to be spaced apart at a certain distance, thereby reducing the contact area between the wafer 200 and the supporting plate 21 on the one hand, and facilitating the reaction and preparation of the wafer 200 in the manufacturing process on the other hand. For example, it may facilitate the operation of the device on the lower surface of the wafer 200. In some embodiments, as shown in FIGS. 4 and 5, the plurality of protrusions 23 are evenly arranged and spaced apart from each other along the circumference of the supporting plate 21. In some embodiments, when the wafer 200 is placed on the supporting plate 21, the plurality of protrusions 23 may be positioned around the center of the wafer 200. The contact surface of the protrusions 23 with the wafer 200 may be a curved surface, for example, the protrusions 23 may be a spherical shape.

The embodiment of the disclosure further provides a wafer boat assembly.

The wafer boat assembly according to the embodiment of the disclosure includes the wafer boat structure 100 according to the abovementioned embodiment of the disclosure, and a wafer conveying device. As shown in FIG. 2, the wafer conveying device includes a wafer conveying arm 300. The wafer conveying arm 300 is in the form of a U-shaped structure. An opening of the U-shaped structure faces towards the wafer boat structure 100, the width of the opening of the U-shaped structure is larger than the maximum width of the supporting plate 21, and thus the supporting plate 21 can pass through the opening of the U-shaped structure.

When the wafer conveying arm 300 conveys the wafer 200, the wafer conveying arm 300 may extend into the wafer boat structure 100. The U-shaped structure of the wafer conveying arm 300 then may pass through the supporting plate 21 to be located on the outer side of the supporting plate 21, so that the wafer 200 can be conveniently grabbed, and collision between the wafer conveying arm 300 and the supporting plate 21 is avoided.

In some embodiments, as shown in FIG. 2, the wafer conveying arm 300 includes a first flat plate 31 and a second flat plate 32 parallel to each other, and a connecting plate 33. The connecting plate 33 is in an arc shape and connected to the first flat plate 31 and the second flat plate 32 respectively. A vertical distance between the first flat plate 31 and the second flat plate 32 is greater than the maximum width of the supporting plate 21, for example, the vertical distance between the first flat plate 31 and the second flat plate 32 may be 150 mm to 200 mm so as to be able to keep away from the supporting plate 21 when conveying the wafer 200. It should be understood that the specific distance between the first flat plate 31 and the second flat plate 32 may be determined according to the actual size of the supporting plate 21, or may be determined based on the size of the conveyed wafer 200. Therefore, when the wafer conveying arm 300 grabs the wafer, the wafer conveying arm 300 may avoid the supporting plate 21, so that the wafer conveying arm 300 is prevented from colliding with the wafer supporting part.

The embodiment of the disclosure further provides a diffusion furnace.

The diffusion furnace (not shown) according to the embodiment of the disclosure includes the wafer boat structure 100 of the abovementioned embodiment. By arranging the wafer boat structure 100, the breakage of the wafer 200 may be reduced, the problem of film thickness in the center and at the edge of the wafer 200 may also be avoided, and the product yield is improved.

The foregoing is merely some embodiments of the disclosure, it should be noted that those of ordinary skill in the art can also make some modifications and improvements without departing from the concept of the disclosure, and these modifications and improvements all fall within the scope of protection of the disclosure.

1. A wafer boat structure, comprising:
a supporting frame, comprising an upper supporting member and a lower supporting member, a plurality of supporting rods being arranged between the upper supporting member and the lower supporting member, one end of each of the supporting rods being connected with the upper supporting member and the other end being connected with the lower supporting member, the plurality of supporting rods being spaced apart from each other in a circumferential direction of the upper supporting member, and an opening for access of wafers is formed between each two adjacent supporting rods; and
at least one wafer supporting part arranged on the supporting rods for supporting the wafer, the wafer supporting part comprising a supporting plate and at least one wafer board, the supporting plate and the at least one wafer board supporting the same wafer, the supporting plate being connected with the supporting rod and a position of the supporting plate corresponding to central positions of the upper supporting member and the lower supporting member, the wafer board being arranged on an inner side of the supporting rod to support a edge of the wafer.

2. The wafer boat structure of claim 1, wherein the wafer supporting part further comprises connecting rods connected to the supporting rod and to the supporting plate.

3. The wafer boat structure of claim 2, wherein the wafer supporting part comprises at least two connecting rods, and the at least two connecting rods are connected with at least two of the supporting rods in a one-to-one correspondence.

4. The wafer boat structure of claim 2, wherein the connecting rods are arranged on a side of the supporting plate away from and opposite to the opening.

5. The wafer boat structure of claim 2, wherein an upper surface of the supporting plate is flush with an upper surface of the wafer board of the same wafer supporting part and is higher than an upper surface of the connecting rod.

6. The wafer boat structure of claim 1, wherein the supporting plate is in a round shape.

7. The wafer boat structure of claim 6, wherein the supporting plate has a diameter of 90 mm to 110 mm.

8. The wafer boat structure of claim 1, wherein the supporting plate is in a ring shape.

9. The wafer boat structure of claim 8, wherein the supporting plate is in a circular ring shape, an inner ring diameter of the supporting plate is 90 mm to 110 mm, and a width of the supporting plate is 6 mm to 10 mm.

10. The wafer boat structure of claim 1, wherein a plurality of wafer boards are regularly distributed around a circumference of the supporting plate.

11. The wafer boat structure of claim 1, wherein the wafer boat structure comprises a plurality of wafer supporting parts arranged to be spaced apart from each other in an axial direction of the supporting rod.

12. The wafer boat structure of claim 1, wherein a plurality of protrusions are formed on the supporting plate to support the wafer.

13. The wafer boat structure of claim 12, wherein the plurality of protrusions are evenly arranged and spaced apart from each other along a circumference of the supporting plate.

14. A wafer boat assembly, comprising a wafer boat structure and a wafer conveying device,
wherein the wafer boat structure comprises:
a supporting frame, comprising an upper supporting member and a lower supporting member, a plurality of supporting rods being arranged between the upper supporting member and the lower supporting member, one end of each of the supporting rods being connected with the upper supporting member and the other end being connected with the lower supporting member, the plurality of supporting rods being spaced apart from each other in a circumferential direction of the upper supporting member, and an opening for access of wafers is formed between each two adjacent supporting rods; and
at least one wafer supporting part arranged on the supporting rods for supporting the wafer, the wafer supporting part comprising a supporting plate and at least one wafer board, the supporting plate and the at least one wafer board supporting the same wafer, the supporting plate being connected with the supporting rod and a position of the supporting plate corresponding to central positions of the upper supporting member and the lower supporting member, the wafer board being arranged on an inner side of the supporting rod to support a edge of the wafer, and
wherein the wafer conveying device comprises a wafer conveying arm, the wafer conveying arm being in the form of a U-shaped structure, an opening of the U-shaped structure facing towards the wafer boat structure, a width of the opening of the U-shaped structure being larger than a maximum width of the supporting plate, for passage of the wafers through the supporting plate.

15. The wafer boat assembly of claim 14, wherein the wafer conveying arm comprises a first flat plate and a second flat plate parallel to each other as well as a connecting plate, the connecting plate being in an arc shape and connected to the first flat plate and the second flat plate, a vertical distance between the first flat plate and the second flat plate is 150 mm to 200 mm.

16. A diffusion furnace, wherein the diffusion furnace comprises a wafer boat structure, the wafer boat structure comprising:
a supporting frame, comprising an upper supporting member and a lower supporting member, a plurality of supporting rods being arranged between the upper supporting member and the lower supporting member, one end of each of the supporting rods being connected with the upper supporting member and the other end being connected with the lower supporting member, the plurality of supporting rods being spaced apart from each other in a circumferential direction of the upper supporting member, and an opening for access of wafers is formed between each two adjacent supporting rods; and
at least one wafer supporting part arranged on the supporting rods for supporting the wafer, the wafer supporting part comprising a supporting plate and at least one wafer board, the supporting plate and the at least one wafer board supporting the same wafer, the supporting plate being connected with the supporting rod and a position of the supporting plate corresponding to central positions of the upper supporting member and the lower supporting member, the wafer board being arranged on an inner side of the supporting rod to support a edge of the wafer.
